(19) United States
(12) Patent Application Publication
(10) Pub. No.: US 2024/0379545 A1
(43) Pub. Date: Nov. 14, 2024

(54) SEMICONDUCTOR DEVICES

(71) Applicant: SAMSUNG ELECTRONICS CO., LTD., Suwon-si (KR)

(72) Inventors: Jeong Wan HAN, Suwon-si (KR); Bona BAEK, Suwon-si (KR); Byungkeun KIM, Suwon-si (KR); Young-Hoo KIM, Suwon-si (KR); Jeonghun KIM, Suwon-si (KR)

(21) Appl. No.: 18/427,135

(22) Filed: Jan. 30, 2024

(30) Foreign Application Priority Data
May 12, 2023 (KR) 10-2023-0061655

(51) Int. Cl. H01L 23/528; H01L 23/532

(52) U.S. Cl. CPC H01L 23/5283; H01L 23/53209

(57) ABSTRACT

A semiconductor device comprising: a substrate; and a conductive structure on the substrate, wherein the conductive structure comprises: a lower conductive structure comprising a lower conductive pattern; and an upper conductive structure comprising an upper conductive pattern, wherein the upper conductive structure is on the lower conductive structure, wherein at least one of a first side surface of the lower conductive pattern or a second side surface of the upper conductive pattern comprises a rough surface, and wherein a first width of a lower surface of the upper conductive pattern in a first direction parallel to a lower surface of the substrate is substantially equal to or less than a second width of an upper surface of the lower conductive pattern in the first direction.

### CROSS-REFERENCE TO RELATED APPLICATIONS

This U.S. non-provisional patent application claims priority under 35 U.S.C. § 119 to Korean Patent Application No. 10-2023-0061655, filed on May 12, 2023, in the Korean Intellectual Property Office, the entire contents of which are hereby incorporated by reference.

### BACKGROUND OF THE INVENTION

The present disclosure relates to semiconductor devices and methods of manufacturing the same.

Semiconductor devices are widely used in an electronic industry because of their small sizes, multi-functional characteristics, and/or low manufacturing costs. Semiconductor devices may be categorized as any one of semiconductor memory devices for storing logical data, semiconductor logic devices for processing logical data, and hybrid semiconductor devices having both the function of the semiconductor memory devices and the function of the semiconductor logic devices.

High-speed and low-voltage semiconductor memory devices have been demanded to satisfy characteristics (e.g., high speed and/or low power consumption) of electronic devices including semiconductor memory devices. Semiconductor memory devices have been highly integrated to meet these demands. Thus, various techniques for improving the integration density of semiconductor memory devices have been studied.

### SUMMARY

Embodiments of the inventive concepts may provide a semiconductor device with improved reliability.

In an aspect, a semiconductor device comprising: a substrate; and a conductive structure on the substrate, wherein the conductive structure comprises: a lower conductive structure comprising a lower conductive pattern; and an upper conductive structure comprising an upper conductive pattern, wherein the upper conductive structure is on the lower conductive structure, wherein at least one of a first side surface of the lower conductive pattern or a second side surface of the upper conductive pattern comprises a rough surface, and wherein a first width of a lower surface of the upper conductive pattern in a first direction parallel to a lower surface of the substrate is substantially equal to or less than a second width of an upper surface of the lower conductive pattern in the first direction.

In an aspect, a semiconductor device comprising: a substrate; and a conductive structure on the substrate, wherein the conductive structure comprises: a lower conductive structure comprising a lower conductive pattern; and an upper conductive structure comprising an upper conductive pattern, wherein the upper conductive structure is on the lower conductive structure, wherein at least one of a first side surface of the lower conductive pattern or a second side surface of the upper conductive pattern comprises a rough surface, and wherein the upper conductive pattern and the lower conductive pattern are in contact with each other with an interface interposed therebetween.

In an aspect, a semiconductor device comprising: a substrate; and a first conductive structure on the substrate and a second conductive structure on the first conductive structure, wherein each of the first and second conductive structures comprises: a lower conductive structure comprising a lower conductive pattern; and an upper conductive structure comprising an upper conductive pattern, wherein at least one of a first side surface of the lower conductive pattern of the second conductive structure or a second side surface of the upper conductive pattern of the second conductive structure comprises a rough surface, and wherein a width of a lower surface of the upper conductive pattern of the second conductive structure in a first direction parallel to a lower surface of the substrate is substantially equal to or less than a width of an upper surface of the lower conductive pattern of the second conductive structure in the first direction.

### BRIEF DESCRIPTION OF THE DRAWINGS

FIG. 1 is a cross-sectional view illustrating a semiconductor device according to some embodiments of the inventive concepts.

FIG. 2 is a cross-sectional view illustrating a semiconductor device according to some embodiments of the inventive concepts.

FIG. 3 is a cross-sectional view illustrating a semiconductor device according to some embodiments of the inventive concepts.

FIG. 4 is a cross-sectional view illustrating a semiconductor device according to some embodiments of the inventive concepts.

FIG. 5 is a cross-sectional view illustrating a semiconductor device according to some embodiments of the inventive concepts.

FIG. 6 is a cross-sectional view illustrating a semiconductor device according to some embodiments of the inventive concepts.

FIGS. 7 to 9 are cross-sectional views illustrating a method of manufacturing a semiconductor device according to some embodiments of the inventive concepts.

FIGS. 10 to 13 are cross-sectional views illustrating a method of manufacturing a semiconductor device according to some embodiments of the inventive concepts.

FIG. 14 is a cross-sectional view illustrating a method of manufacturing a semiconductor device according to some embodiments of the inventive concepts.

FIG. 15 is a cross-sectional view illustrating a method of manufacturing a semiconductor device according to some embodiments of the inventive concepts.

FIGS. 16 to 18 are cross-sectional views illustrating a method of manufacturing a semiconductor device according to some embodiments of the inventive concepts.

### DETAILED DESCRIPTION

Example embodiments of the inventive concepts will now be described more fully with reference to the accompanying drawings.

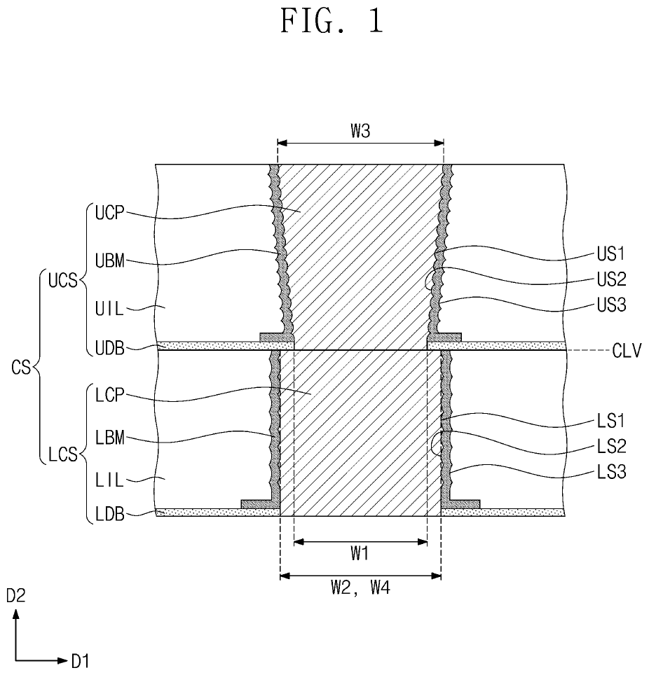

FIG. 1 is a cross-sectional view illustrating a semiconductor device according to some embodiments of the inventive concepts. A semiconductor device according to some embodiments of the inventive concepts will be described with reference to FIG. 1.

Referring to FIG. 1, the semiconductor device may include a conductive structure CS. The conductive structure CS may include a lower conductive structure LCS and an upper conductive structure UCS, which are sequentially stacked in a direction perpendicular to a lower surface of a substrate 100 to be described later (also referred to as a second direction D2 or a vertical direction). For example, the upper conductive structure UCS and the lower conductive structure LCS may be distinguished from each other with an interface interposed therebetween at a contact level CLV. For example, the contact level CLV may be defined at a level at which an upper conductive pattern UCP to be described later is in contact with a lower conductive pattern LCP to be described later. A “level”, “height”, “higher”, “lower”, or the like herein may refer to a relative distance from the lower surface of the substrate 100 in the vertical direction. For example, when an element “A” is higher than an element “B” may mean that the element “A” is farther than the element “B” from the lower surface of the substrate 100 in the vertical direction.

The upper conductive structure UCS may include an upper conductive pattern UCP, an upper barrier pattern UBM, an upper insulating layer UIL, and an upper diffusion barrier layer UDB. The lower conductive structure LCS may include a lower conductive pattern LCP, a lower barrier pattern LBM, a lower insulating layer LIL, and a lower diffusion barrier layer LDB.

The conductive structure CS may be a circuit structure for driving a semiconductor layer 200 to be described later. For example, the upper conductive structure UCS may include an interconnection structure of the circuit structure, and the upper conductive pattern UCP may include an interconnection line of the interconnection structure. For example, the lower conductive structure LCS may include a via structure of the circuit structure, and the lower conductive pattern LCP may include a via pattern of the via structure.

The upper conductive pattern UCP may be located on the lower conductive pattern LCP. The upper conductive pattern UCP may vertically overlap with the lower conductive pattern LCP. For example, the upper conductive pattern UCP may overlap with the lower conductive pattern LCP in the vertical direction. As used herein, “an element A overlapping an element B in a direction X” (or similar language) means that there is at least one line that extends in the direction X and intersects both the elements A and B. The upper conductive pattern UCP and the lower conductive pattern LCP may be distinguished from each other at the contact level CLV with an interface interposed therebetween and may be in contact with each other. For example, the contact level CLV may be defined at a level at which a lower surface of the upper conductive pattern UCP and an upper surface of the lower conductive pattern LCP are located. At the contact level CLV, the upper conductive pattern UCP may have a first width W1 in a first direction D1, and the lower conductive pattern LCP may have a second width W2 in the first direction D1. For example, the lower surface of the upper conductive pattern UCP may have the first width W1 in the first direction D1, and the upper surface of the lower conductive pattern LCP may have the second width W2 in the first direction D1. An upper surface of the upper conductive pattern UCP may have a third width W3 in the first direction D1, and a lower surface of the lower conductive pattern LCP may have a fourth width W4 in the first direction D1. The first direction D1 may be a direction parallel to the lower surface of the substrate 100. For example, the first width W1 may be substantially equal to or less than the second width W2. For example, the first width W1 may be substantially equal to or less than the third width W3. For some examples, the second width W2 may be substantially equal to the fourth width W4. For certain examples, the second width W2 may be greater or less than the fourth width W4. Each of the upper conductive pattern UCP and the lower conductive pattern LCP may include, for example, a metal material (e.g., Ti, Mo, W, Cu, Al, Au, Ta, Ru, Ir, etc.).

Each of a side surface US1 of the upper conductive pattern UCP and a side surface LS1 of the lower conductive pattern LCP may be roughened. In the present specification, it may be understood that when a surface is roughened, a surface of a material (an element) may be rough. Thus, the roughened surface may not be smooth but may be uneven. As used herein, the term, roughened, may also be referred to as bumpy, rugged, jagged and/or the like (i.e., not smooth). More particularly, a large-sized grain of the surface of the material (the element) may be removed more slowly than a small-sized grain of the surface of the material (the element) in an etching process. Thus, the large-sized grain may not be removed or may be partially removed, and the small-sized grains between the large-sized grains may be removed. As a result, the surface of the material (the element) may be roughened. For example, the upper surface of each of the upper conductive pattern UCP and the lower conductive pattern LCP may be smooth, but embodiments of the inventive concepts are not limited thereto.

The upper barrier pattern UBM may be on (e.g., at least partially cover or overlap) the side surface US1 of the upper conductive pattern UCP. In some embodiments, an inner side surface US2 of the upper barrier pattern UBM may be roughened. In some embodiments, an outer side surface US3 of the upper barrier pattern UBM may be roughened. A portion of the upper barrier pattern UBM may extend on the upper diffusion barrier layer UDB (to be described later in detail) in a direction (e.g., the first direction D1) which is parallel to the lower surface of the substrate 100 and is away from a center portion of the upper conductive pattern UCP. The portion of the upper barrier pattern UBM may be in contact with the upper diffusion barrier layer UDB. The upper barrier pattern UBM may be spaced apart from the lower conductive pattern LCP and the lower barrier pattern LBM by the upper diffusion barrier layer UDB. A lower surface of the upper barrier pattern UBM may be located at a level higher than the contact level CLV.

The lower barrier pattern LBM may be on (e.g., at least partially cover or overlap) the side surface LS1 of the lower conductive pattern LCP. In some embodiments, an inner side surface LS2 of the lower barrier pattern LBM may be roughened. In some embodiments, an outer side surface LS3 of the lower barrier pattern LBM may be roughened. A portion of the lower barrier pattern LBM may extend on the lower diffusion barrier layer LDB (to be described later in detail) in a direction (e.g., the first direction D1) which is parallel to the lower surface of the substrate 100 and is away from a center portion of the lower conductive pattern LCP. The portion of the lower barrier pattern LBM may be in contact with the lower diffusion barrier layer LDB. A lower surface of the lower barrier pattern LBM may be located at a higher level than the lower surface of the lower conductive pattern LCP. Each of the lower barrier pattern LBM and the upper barrier pattern UBM may include, for example, a nitride of a metal material (e.g., a nitride of Ti, Mo, W, Cu, Al, Ta, Ru, Ir, etc.).

The upper insulating layer UIL may be on (e.g., at least partially cover or overlap) the side surface US1 of the upper conductive pattern UCP and the inner side surface US2 and the outer surface US3 of the upper barrier pattern UBM. An inner side surface of the upper insulating layer UIL may be roughened. The upper insulating layer UIL may be located between a level of the upper surface of the upper conductive pattern UCP and a level of an upper surface of the upper diffusion barrier layer UDB. The upper insulating layer UIL may be spaced apart from the lower conductive pattern LCP, the lower barrier pattern LBM and the lower insulating layer LIL by the upper diffusion barrier layer UDB.

The lower insulating layer LIL may be on (e.g., at least partially cover or overlap) the side surface LS1 of the lower conductive pattern LCP and the inner side surface LS2 and the outer surface LS3 of the lower barrier pattern LBM. An inner side surface of the lower insulating layer LIL may be roughened. The lower insulating layer LIL may be located between a lower surface of the upper diffusion barrier layer UDB and an upper surface of the lower diffusion barrier layer LDB. An upper surface of the lower insulating layer LIL may be located at substantially the same level as the contact level CLV. Each of the upper insulating layer UIL and the lower insulating layer LIL may include a low-k material. For example, the low-k material may include SiCOH.

According to some embodiments of the inventive concepts, the side surface US1 of the upper conductive pattern UCP and the side surface of LS1 of the lower conductive pattern LCP may be roughened. Thus, an overlapping area (e.g., the upper barrier pattern UBM) between the upper conductive pattern UCP and the upper insulating layer UIL and an overlapping area (e.g., the lower barrier pattern LBM) between the lower conductive pattern LCP and the lower insulating layer LIL may be widened. As a result, adhesion between the upper conductive pattern UCP and the upper insulating layer UIL and/or between the lower conductive pattern LCP and the lower insulating layer LIL may be increased and/or enhanced to reduce (e.g., prevent) a delamination phenomenon and/or a crack. Thus, reliability of the semiconductor device may be improved. In the present specification, the term ‘A or B’, ‘at least one of A and B’, ‘at least one of A or B’, ‘A, B, or C’, ‘at least one of A, B, and C’, or ‘at least one of A, B, or C’ may include any and all combinations of one or more of the associated listed items.

The upper diffusion barrier layer UDB may be located between the upper insulating layer UIL and the lower insulating layer LIL. The upper diffusion barrier layer UDB may be on (e.g., at least partially cover or overlap) a portion of the side surface US1 of the upper conductive pattern UCP. For example, the upper diffusion barrier layer UDB may be in contact with the portion of the side surface US1 of the upper conductive pattern UCP. For example, the portion of the side surface US1 of the upper conductive pattern UCP, which is covered or overlapped by the upper diffusion barrier layer UDB, may not be roughened. The upper diffusion barrier layer UDB may be on (e.g., at least partially cover or overlap) the lower surface of the upper barrier pattern UBM. The lower surface of the upper diffusion barrier layer UDB may be located at substantially the same level as the contact level CLV. The upper diffusion barrier layer UDB may be on (e.g., at least partially cover or overlap) the upper surface of the lower conductive pattern LCP, an upper surface of the lower barrier pattern LBM, and the upper surface of the lower insulating layer LIL.

The lower diffusion barrier layer LDB may be located under the lower insulating layer LIL. For example, the lower insulating layer LIL may be on the lower diffusion barrier layer LDB. The lower diffusion barrier layer LDB may be on (e.g., at least partially cover or overlap) a portion of the side surface LS1 of the lower conductive pattern LCP. For example, the lower diffusion barrier layer LDB may be in contact with the portion of the side surface LS1 of the lower conductive pattern LCP. The portion of the side surface LS1 of the lower conductive pattern LCP, which is covered or overlapped by the lower diffusion barrier layer LDB, may not be roughened. The lower diffusion barrier layer LDB may be on (e.g., at least partially cover or overlap) the lower surface of the lower barrier pattern LBM. Each of the upper diffusion barrier layer UDB and the lower diffusion barrier layer LDB may include SiCN.

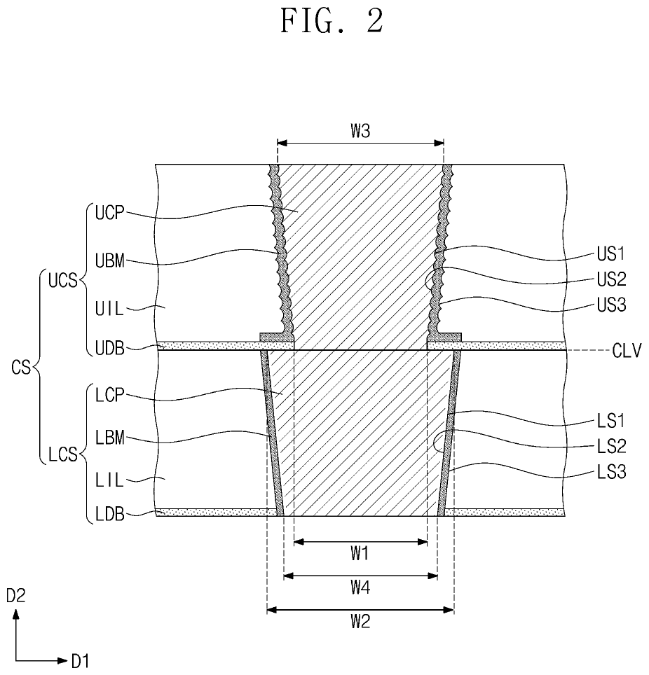

FIG. 2 is a cross-sectional view illustrating a semiconductor device according to some embodiments of the inventive concepts. A semiconductor device according to some embodiments of the inventive concepts will be described with reference to FIG. 2. Differences between the present embodiments and the above embodiments will be mainly described for the purpose of ease and convenience in explanation.

Referring to FIG. 2, the side surface US1 of the upper conductive pattern UCP may be roughened, and a side surface LS1 of the lower conductive pattern LCP may not be roughened. For example, the side surface LS1 of the lower conductive pattern LCP may be smooth, but embodiments of the inventive concepts are not limited thereto. In some embodiments, the second width W2 may be greater than the fourth width W4.

An inner side surface LS2 and an outer side surface LS3 of the lower barrier pattern LBM may not be roughened. The lower barrier pattern LBM may be on (e.g., at least partially cover or overlap) the side surface LS1 of the lower conductive pattern LCP and may extend between the lower conductive pattern LCP and the lower diffusion barrier layer LDB. A lower surface of the lower barrier pattern LBM may be located at substantially the same level as the lower surface of the lower conductive pattern LCP. The lower barrier pattern LBM may be on (e.g., at least partially cover or overlap) an inner side surface of the lower diffusion barrier layer LDB.

An inner side surface of the lower insulating layer LIL may not be roughened. The lower surface of the lower insulating layer LIL may be located at a higher level than the lower surface of the lower barrier pattern LBM. The lower insulating layer LIL may be on (e.g., at least partially cover or overlap) the outer surface LS3 of the lower barrier pattern LBM. In some embodiments, the lower insulating layer LIL may not be in contact with a portion of the outer side surface LS3 of the lower barrier pattern LBM. For example, the outer side surface LS3 of the lower barrier pattern LBM may have a portion that is not in contact with (i.e., spaced apart from) the lower insulating layer LIL.

The lower diffusion barrier layer LDB may be spaced apart from the lower conductive pattern LCP by the lower barrier pattern LBM. The lower diffusion barrier layer LDB may be in contact with the outer side surface LS3 of the lower barrier pattern LBM. The lower surface of the lower diffusion barrier layer LDB and the lower surface of the lower barrier pattern LBM may be located at substantially the same level and may be substantially coplanar with each other.

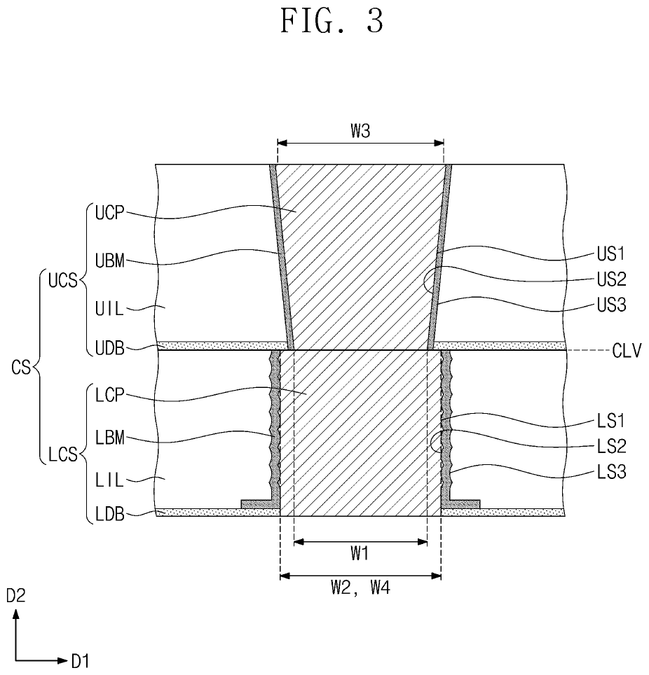

FIG. 3 is a cross-sectional view illustrating a semiconductor device according to some embodiments of the inventive concepts. A semiconductor device according to some embodiments of the inventive concepts will be described with reference to FIG. 3. Differences between the present embodiments and the above embodiments will be mainly described for the purpose of ease and convenience in explanation.

Referring to FIG. 3, the side surface US1 of the upper conductive pattern UCP may not be roughened, and the side surface LS1 of the lower conductive pattern LCP may be roughened. For example, the side surface US1 of the upper conductive pattern UCP may be smooth, but embodiments of the inventive concepts are not limited thereto. In some embodiments, the first width W1 may be less than the third width W3.

An inner side surface US2 and an outer side surface US3 of the upper barrier pattern UBM may not be roughened. The upper barrier pattern UBM may be on (e.g., at least partially) cover the side surface US1 of the upper conductive pattern UCP and may extend between the upper conductive pattern UCP and the upper diffusion barrier layer UDB. A lower surface of the upper barrier pattern UBM may be located at substantially the same level as the lower surface of the upper conductive pattern UCP. The upper barrier pattern UBM may be on (e.g., at least partially cover or overlap) an inner side surface of the upper diffusion barrier layer UDB.

An inner side surface of the upper insulating layer UIL may not be roughened. A lower surface of the upper insulating layer UIL may be located at a higher level than the lower surface of the upper barrier pattern UBM. The upper insulating layer UIL may be on (e.g., at least partially cover or overlap) the outer surface US3 of the upper barrier pattern UBM. In some embodiments, the upper insulating layer UIL may not be in contact with a portion of the outer side surface US3 of the upper barrier pattern UBM. For example, the outer side surface US3 of the upper barrier pattern UBM may have a portion that is not in contact with the upper insulating layer UIL.

The upper diffusion barrier layer UDB may be spaced apart from the upper conductive pattern UCP by the upper barrier pattern UBM. The upper diffusion barrier layer UDB may be in contact with the outer side surface US3 of the upper barrier pattern UBM. The lower surface of the upper diffusion barrier layer UDB and the lower surface of the upper barrier pattern UBM may be located at substantially the same level and may be substantially coplanar with each other.

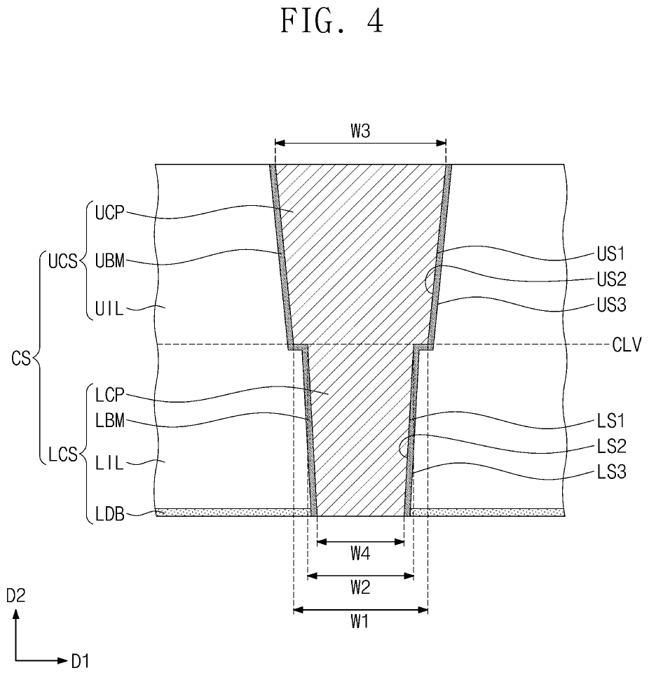

FIG. 4 is a cross-sectional view illustrating a semiconductor device according to some embodiments of the inventive concepts. A semiconductor device according to some embodiments of the inventive concepts will be described with reference to FIG. 4. Differences between the present embodiments and the above embodiments will be mainly described for the purpose of ease and convenience in explanation.

Referring to FIG. 4, an upper conductive structure UCS and a lower conductive structure LCS may be distinct from each other at the contact level CLV without an interface (e.g., without a visible interface) therebetween. For example, unlike FIGS. 1 to 3, the upper conductive structure UCS may not include the upper diffusion barrier layer UDB.

The side surface US1 of the upper conductive pattern UCP and the side surface LS1 of the lower conductive pattern LCP may not be roughened. For example, the side surface US1 of the upper conductive pattern UCP and the side surface LS1 of the lower conductive pattern LCP may be smooth, but embodiments of the inventive concepts are not limited thereto. In some embodiments, the upper conductive pattern UCP and the lower conductive pattern LCP may be distinguished from each other at the contact level CLV without an interface (e.g., a visible interface) therebetween and may be in contact with each other. In some embodiments, the first width W1 may be greater than the second width W2. In some embodiments, the first width W1 may be less than the third width W3. In some embodiments, the first width W1 may be greater than the fourth width W4. In some embodiments, the second width W2 may be greater than the fourth width W4.

The upper barrier pattern UBM and the lower barrier pattern LBM may be distinguished from each other at the contact level CLV without an interface (e.g., a visible interface) therebetween and may be in contact with each other. The inner side surfaces US2 and LS2 of the upper barrier pattern UBM and the lower barrier pattern LBM may not be roughened. In some embodiments, the outer side surfaces US3 and LS3 of the upper barrier pattern UBM and the lower barrier pattern LBM may not be roughened. A portion of the lower barrier pattern LBM may extend on the lower surface of the upper conductive pattern UCP in a direction away from the center portions of the lower conductive pattern LCP. The lower barrier pattern LBM may be in contact with the lower surface of the upper conductive pattern UCP. The upper surface of the lower barrier pattern LBM may be located at substantially the same level as the contact level CLV.

The inner side surfaces of the upper insulating layer UIL and the lower insulating layer LIL may not be roughened. The upper insulating layer UIL and the lower insulating layer LIL may be distinguished from each other at the contact level CLV without an interface (e.g., a visible interface) therebetween and may be in contact with each other.

The lower diffusion barrier layer LDB may be spaced apart from the lower conductive pattern LCP by the lower barrier pattern LBM. The lower diffusion barrier layer LDB may be in contact with the outer side surface LS3 of the lower barrier pattern LBM. The lower surface of the lower diffusion barrier layer LDB and the lower surface of the lower barrier pattern LBM may be located at substantially the same level and may be substantially coplanar with each other.

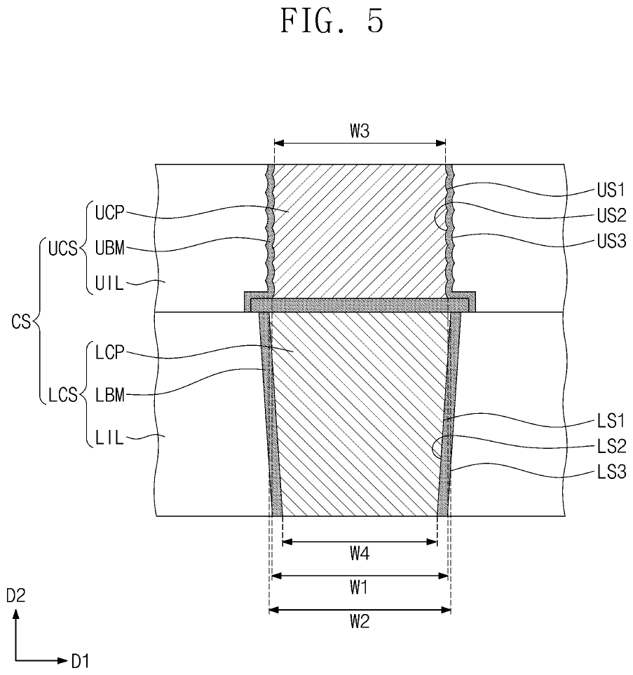

FIG. 5 is a cross-sectional view illustrating a semiconductor device according to some embodiments of the inventive concepts. A semiconductor device according to some embodiments of the inventive concepts will be described with reference to FIG. 5. Differences between the present embodiments and the above embodiments will be mainly described for the purpose of ease and convenience in explanation.

Referring to FIG. 5, in certain embodiments, the upper conductive structure UCS may not include the upper diffusion barrier layer UDB. In certain embodiments, the lower conductive structure LCS may not include the lower diffusion barrier layer LDB.

The side surface US1 of the upper conductive pattern UCP may be roughened, and the side surface LS1 of the lower conductive pattern LCP may not be roughened. In certain embodiments, even though not shown in the drawings, the side surface LS1 of the lower conductive pattern LCP may be roughened. In certain embodiments, even though not shown in the drawings, the side surface US1 of the upper conductive pattern UCP and the side surface LS1 of the lower conductive pattern LCP may not be roughened. A width, in the first direction D1, of the upper surface of the upper conductive pattern UCP may be substantially equal to a width, in the first direction D1, of the lower surface of the upper conductive pattern UCP. Alternatively, the width, in the first direction D1, of the upper surface of the upper conductive pattern UCP may be greater or less than the width, in the first direction D1, of the lower surface of the upper conductive pattern UCP. A width, in the first direction D1, of the upper surface of the lower conductive pattern LCP may be greater than a width, in the first direction D1, of the lower surface of the lower conductive pattern LCP. In some embodiments, the upper conductive pattern UCP may be spaced apart from the lower conductive pattern LCP by a lower barrier pattern LBM. In some embodiments, the upper conductive pattern UCP and the lower conductive pattern LCP may include the same metal material or different metal materials (e.g., Ti, Mo, W, Cu, Al, Au, Ta, Ru, Ir, etc.). For example, the lower conductive pattern LCP may include tungsten (W).

The inner side surface US2 and the outer side surface US3 of the upper barrier pattern UBM may be roughened. In some embodiments, a lower surface of the upper barrier pattern UBM may be located at a lower level than a lower surface of the upper conductive pattern UCP. However, embodiments of the inventive concepts are not limited thereto. In certain embodiments, even though not shown in the drawings, the lower surface of the upper barrier pattern UBM may be located at substantially the same level as the lower surface of the upper conductive pattern UCP.

A first portion of the lower barrier pattern LBM may be on (e.g., at least partially cover or overlap) the side surface LS1 of the lower conductive pattern LCP. A second portion of the lower barrier pattern LBM may be on (e.g., at least partially cover or overlap) the upper surface of the lower conductive pattern LCP. For example, the second portion of the lower barrier pattern LBM may be located between the upper conductive pattern UCP and the lower conductive pattern LCP. For example, a upper surface of the lower barrier pattern LBM may be located at a higher level than the lower surface of the upper barrier pattern UBM. For example, the upper surface of the lower barrier pattern LBM may be located at a higher level than the upper surface of the lower insulating layer LIL. Each of the lower barrier pattern LBM and the upper barrier pattern UBM may include, for example, a nitride of a metal material (e.g., a nitride of Ti, Mo, W, Cu, Al, Ta, Ru, Ir, etc.).

The inner side surface of the upper insulating layer UIL may be roughened. For example, a lower surface of the upper insulating layer UIL may be located at a lower level than the lower surface of the upper conductive pattern UCP. For example, the upper insulating layer UIL and the lower insulating layer LIL may be distinguished from each other with an interface interposed therebetween and may be in contact with each other. For example, the upper insulating layer UIL and the lower insulating layer LIL may include the same insulating material or different insulating materials. For example, the upper insulating layer UIL may include a low-k material, and the lower insulating layer LIL may include, for example, silicon oxide, silicon nitride, silicon oxynitride, and/or TEOS.

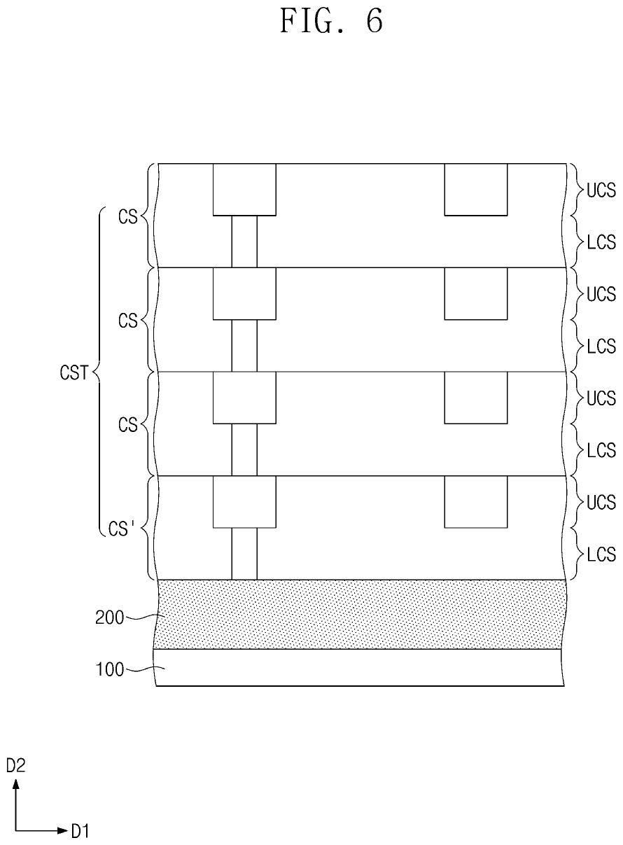

FIG. 6 is a cross-sectional view illustrating a semiconductor device according to some embodiments of the inventive concepts. A semiconductor device according to some embodiments of the inventive concepts will be described with reference to FIG. 6. Differences between the present embodiments and the above embodiments will be mainly described for the purpose of ease and convenience in explanation.

Referring to FIG. 6, a substrate 100 may be provided. The substrate 100 may be a semiconductor substrate such as a silicon substrate, a germanium substrate, or a silicon-germanium substrate.

A semiconductor layer 200 may be provided on the substrate 100. The semiconductor layer 200 may include one or more field effect transistors (FETs). For example, the field effect transistor may be a metal-oxide-semiconductor FET (MOSFET), but embodiments of the inventive concepts are not limited thereto.

A conductive structure stack CST may be located on the semiconductor layer 200. The conductive structure stack CST may be electrically connected to the semiconductor layer 200. The conductive structure stack CST may include a plurality of conductive structures CS' and CS stacked in a second direction D2 on the semiconductor layer 200. The plurality of conductive structures CS' and CS may include a lowermost conductive structure CS' and the other conductive structures CS. The second direction D2 may be a direction perpendicular to the lower surface of the substrate 100. The second direction D2 may be referred to as the vertical direction. The conductive structure stack CST may include a plurality of circuit structures (i.e., the plurality of conductive structures CS' and CS) configured to receive a voltage for controlling driving of the semiconductor layer 200.

Components of the lowermost conductive structure CS' of the plurality of conductive structures CS' and CS may be partially different from components of each of the other conductive structures CS of the plurality of conductive structures CS' and CS. For example, the lowermost conductive structure CS' may be the conductive structure CS described with reference to FIG. 5. In certain embodiments, even though not shown in the drawings, the lower conductive pattern LCP of the lowermost conductive structure CS' may extend into the semiconductor layer 200.

Each of the other conductive structures CS of the plurality of conductive structures CS' and CS except the lowermost conductive structure CS' may be one of the conductive structures CS described with reference to FIGS. 1 to 4 or may be one of various modified embodiments thereof. The conductive structure stack CST includes one lowermost conductive structure CS' and three the other conductive structures CS in FIG. 6, but embodiments of the inventive concepts are not limited thereto. In certain embodiments, the conductive structure stack CST may include one lowermost conductive structure CS' and n the other conductive structures CS, where ‘n’ is an integral number of 1 or more.

The conductive structure stack CST may include a first conductive structure and a second conductive structure, which are sequentially stacked in the second direction D2. The first conductive structure may be one of the plurality of conductive structures CS' and CS. The second conductive structure may be one of the other conductive structures CS, which is located at a higher level than the first conductive structure. In some embodiments, at least one conductive structure CS of the other conductive structures CS may be provided or not be provided between the first and second conductive structures. In some embodiments, at least one conductive structure CS of the other conductive structures CS may be provided or not be provided under the first conductive structure. In some embodiments, at least one conductive structure CS of the other conductive structures may be provided or not be provided on the second conductive structure. For example, the second conductive structure may be one of the conductive structures CS described with reference to FIGS. 1 to 3. For example, the first conductive structure may be one of the conductive structures CS described with reference to FIGS. 1 to 4. In certain embodiments, the first conductive structure may be the lowermost conductive structure CS′, and the first conductive structure may be the conductive structure CS described with reference to FIG. 5.

A conductive insulating layer (not shown) may be located on the conductive structure stack CST. The conductive insulating layer may be on (e.g., at least partially cover or overlap) an upper surface of the conductive structure stack CST. The conductive insulating layer may include an insulating material. For example, the conductive insulating layer may include SiN.

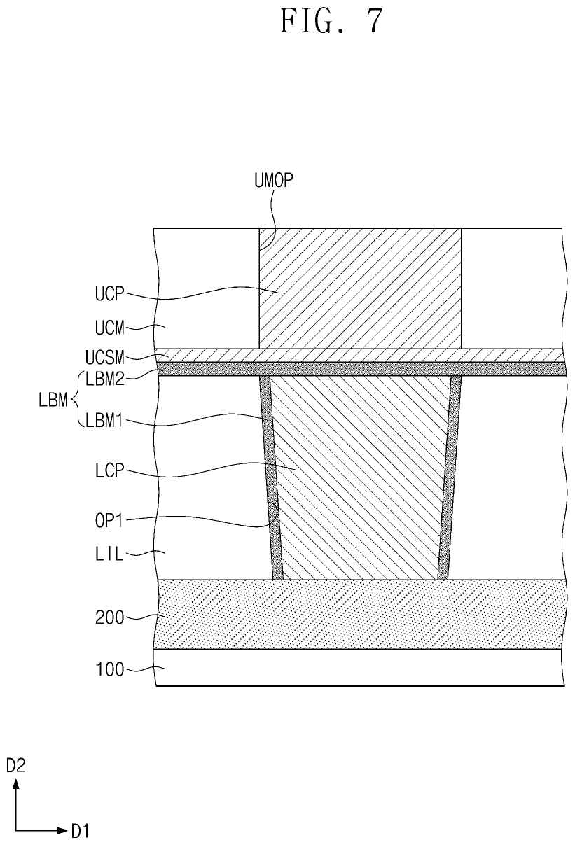

Hereinafter, methods of manufacturing semiconductor devices according to some embodiments of the inventive concepts will be described with reference to FIGS. 7 to 18. The descriptions to the same features as mentioned above will be omitted and differences from the aforementioned features will be mainly described, for the purpose of ease and convenience in explanation.

FIGS. 7 to 9 are cross-sectional views illustrating a method of manufacturing a semiconductor device according to some embodiments of the inventive concepts.

The manufacturing method described with reference to FIGS. 7 to 9 may be a method of manufacturing the conductive structure CS described with reference to FIGS. 5 and 6.

Referring to FIG. 7, a substrate 100 may be provided. A semiconductor layer 200 may be formed on the substrate 100. The formation of the semiconductor layer 200 may include forming field effect transistors using general processes.

A lower insulating layer LIL may be formed on the semiconductor layer 200. For example, the formation of the lower insulating layer LIL may include performing a physical vapor deposition (PVD) process, a chemical vapor deposition (CVD) process, and/or an atomic layer deposition (ALD) process.

Thereafter, a first opening OP1 may be formed in (e.g., to extend in or to penetrate) the lower insulating layer LIL. For example, the formation of the first opening OP1 may include forming a mask pattern (not shown) on the lower insulating layer LIL, and performing a removal process on the lower insulating layer LIL by using the mask pattern as an etch mask.

A lower conductive pattern LCP and a first lower barrier pattern LBM1 may be formed in the first opening OP1. For example, the formation of the lower conductive pattern LCP and the first lower barrier pattern LBM1 may include conformally forming the first lower barrier pattern LBM1 on an inner side surface of the first opening OP1, forming a lower conductive layer (not shown) which fills (a remaining portion of) the first opening OP1 and covers an upper surface of the lower insulating layer LIL, and removing an upper portion of the lower conductive layer to form the lower conductive pattern LCP. For example, the removal of the upper portion of the lower conductive layer may include performing a chemical mechanical polishing (CMP) process on the lower conductive layer.

Thereafter, a second lower barrier pattern LBM2 may be formed on (e.g., at least partially to cover) upper surfaces of the lower insulating layer LIL and the lower conductive pattern LCP. For example, the formation of the second lower barrier pattern LBM2 may include performing a physical vapor deposition (PVD) process. A lower barrier pattern LBM may include the first and second lower barrier patterns LBM1 and LBM2.

An upper conductive seed UCSM may be formed on the lower barrier pattern LBM. For example, the formation of the upper conductive seed UCSM may include performing a physical vapor deposition (PVD) process. For example, the upper conductive seed UCSM may include the same material as an upper conductive pattern UCP.

Thereafter, the upper conductive pattern UCP may be formed on the upper conductive seed UCSM. For example, the formation of the upper conductive pattern UCP may include forming an upper conductive mask pattern UCM including an upper mask opening UMOP on the upper conductive seed UCSM, and forming the upper conductive pattern UCP in the upper mask opening UMOP. For example, the forming of the upper conductive pattern UCP may include performing an electroplating process.

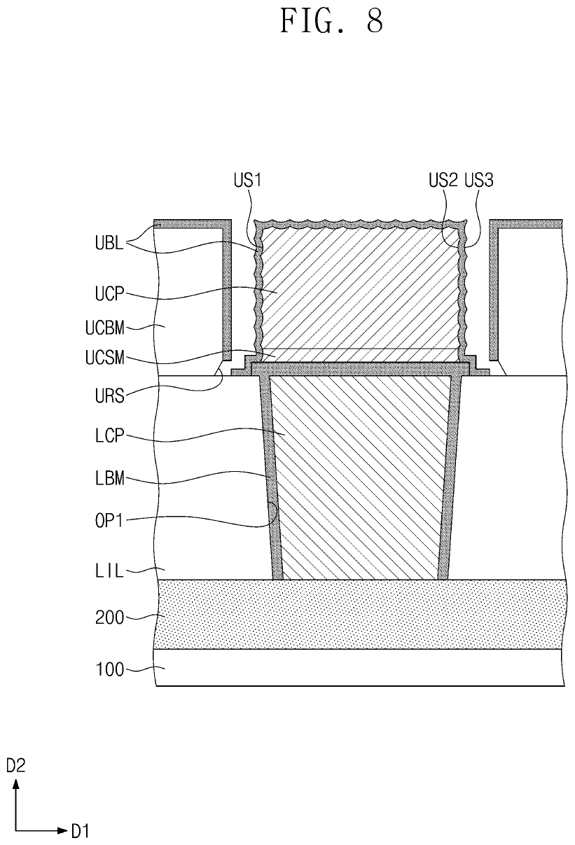

Referring to FIG. 8, the upper conductive mask pattern UCM may be removed. In addition, a portion of the upper conductive seed UCSM and a portion of the lower barrier pattern LBM may be removed. An upper portion of the upper conductive pattern UCP may be removed by the removal process.

Next, a side surface US1 and an upper surface of the upper conductive pattern UCP may be roughened. The roughening process may include an etching process. For example, the etching process may include a CZ treatment process. More particularly, the etching process may remove small-sized grains of a surface of a material and may not remove large-sized grains of the surface of the material or remove a small amount of the large-sized grains. Since the small-sized grains between the large-sized grains are removed, the roughened surface may not be smooth but may be uneven.

Thereafter, an upper barrier mask pattern UCBM may be formed to be spaced apart from the side surface US1 of the upper conductive pattern UCP. For example, as shown in FIG. 8, a lower portion of the upper barrier mask pattern UCBM may be formed to include a horizontally recessed region URS, but embodiments of the inventive concepts are not limited thereto.

An upper barrier layer UBL may be formed on (e.g., at least partially to cover) the upper barrier mask pattern UCBM, the lower insulating layer LIL, the lower barrier pattern LBM, and the upper conductive pattern UCP. For example, the upper barrier layer UBL may be on (e.g., at least partially cover or overlap) the side surface US1 and the upper surface of the upper conductive pattern UCP. For example, the formation of the upper barrier layer UBL may include performing a physical vapor deposition (PVD) process.

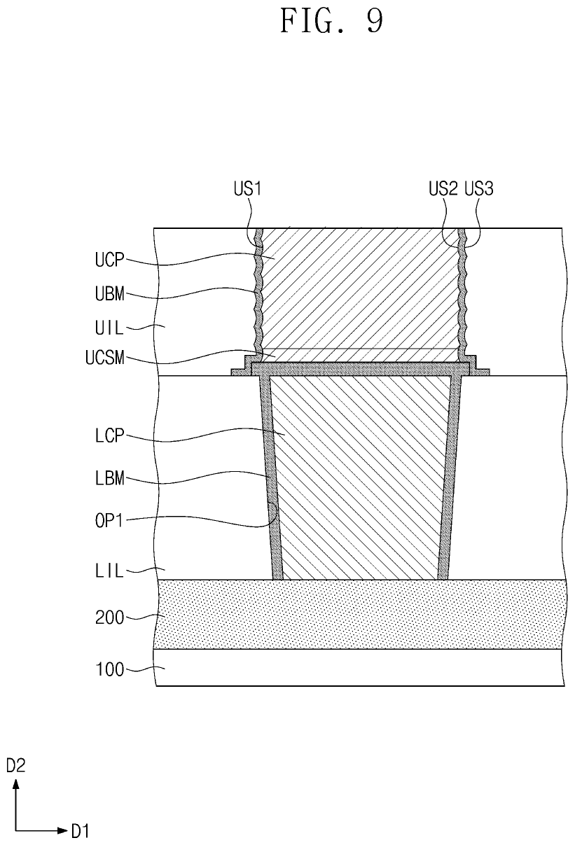

Referring to FIG. 9, an upper barrier pattern UBM may be formed by removing the upper barrier mask pattern UCBM. In the removal process, a portion of the upper barrier layer UBL may also be removed, and a remaining portion of the upper barrier layer UBL may be formed into the upper barrier pattern UBM. The upper barrier pattern UBM may be on (e.g., at least partially cover or overlap) the side surface US1 and the upper surface of the upper conductive pattern UCP. An inner side surface US2, an outer side surface US3, and an upper surface of the upper barrier pattern UBM may be roughened.

Thereafter, an upper insulating layer UIL may be formed on (e.g., at least partially to cover) the side surfaces of the upper conductive pattern UCP and the upper barrier pattern UBM. For example, the formation of the upper insulating layer UIL may include forming an upper insulating layer UIL on an entire upper surface of the substrate 100, and removing an upper portion of the upper insulating layer UIL on the upper surface of the upper conductive pattern UCP. For example, the forming of the upper insulating layer UIL may include performing a physical vapor deposition (PVD) process, a chemical vapor deposition (CVD) process, and/or an atomic layer deposition (ALD) process. For example, the removal of the upper portion of the upper insulating layer UIL may include performing a chemical mechanical polishing (CMP) process on the upper insulating layer UIL. In the removal process, upper portions of the upper conductive pattern UCP and the upper barrier pattern UBM may also be removed. Thus, the upper conductive pattern UCP and the upper barrier pattern UBM may be formed to have smooth upper surfaces, but embodiments of the inventive concepts are not limited thereto.

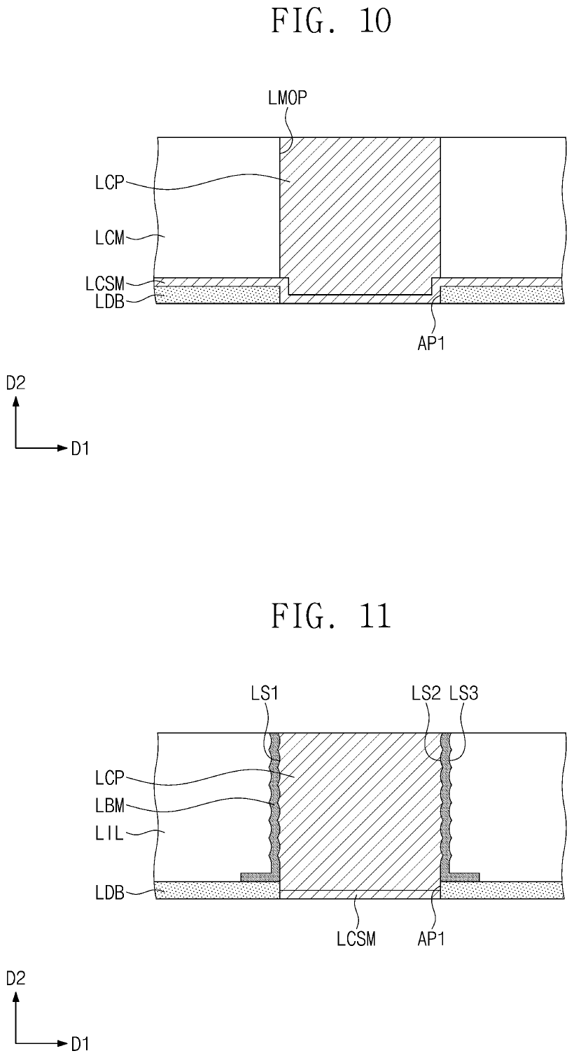

FIGS. 10 to 13 are cross-sectional views illustrating a method of manufacturing a semiconductor device according to some embodiments of the inventive concepts.

The manufacturing method described with reference to FIGS. 10 to 13 may be a method of manufacturing the conductive structure CS described with reference to FIGS. 1 and 6.

Referring to FIG. 10, a lower diffusion barrier layer LDB may be formed. The lower diffusion barrier layer LDB may be formed to have a first aperture AP1. In the case in which the plurality of conductive structures CS' and CS is formed as shown in FIG. 6, the first aperture AP1 may be formed on the upper conductive pattern UCP of one of the conductive structure CS' and CS thereunder. For example, the first aperture AP1 may expose the upper conductive pattern UCP of one of the conductive structure CS' and CS thereunder to the outside. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device. In some embodiments, the formation of the lower diffusion barrier layer LDB may include performing a chemical vapor deposition (CVD) process.

Thereafter, a lower conductive seed LCSM may be formed on (e.g., at least partially to cover) an upper surface of the lower diffusion barrier layer LDB and an inner surface of the first aperture AP1. For example, a process of forming the lower conductive seed LCSM may be similar to the process of forming the upper conductive seed UCSM described with reference to FIG. 7.

A lower conductive pattern LCP may be formed on the lower conductive seed LCSM. For example, a process of forming the lower conductive pattern LCP may be similar to the process of forming the upper conductive pattern UCP described with reference to FIG. 7.

Referring to FIG. 11, a lower conductive mask pattern LCM and a portion of the lower conductive seed LCSM may be removed (e.g., sequentially removed). Thereafter, a side surface LS1 and an upper surface of the lower conductive pattern LCP may be roughened. The roughening process may be substantially the same or similar as described with reference to FIG. 8.

A lower barrier pattern LBM may be formed on (e.g., at least partially to cover) the side surface LS1 of the lower conductive pattern LCP and an upper surface of the lower diffusion barrier layer LDB. An inner side surface LS2, an outer side surface LS3, and an upper surface of the lower barrier pattern LBM may be roughened. For example, the formation of the lower barrier pattern LBM may include forming a lower barrier mask pattern (not shown) spaced apart from the side surface LS1 of the lower conductive pattern LCP, forming a lower barrier layer (not shown) on (e.g., at least partially covering or overlapping) the lower barrier mask pattern, the lower diffusion barrier layer LDB, and the lower conductive pattern LCP, and removing the lower barrier mask pattern. In the process of removing the lower barrier mask pattern, a portion of the lower barrier layer may also be removed, and a remaining portion of the lower barrier layer may be formed into the lower barrier pattern LBM. The lower barrier mask pattern may be formed to include a recessed region, like the upper barrier mask pattern UCBM described with reference to FIG. 8. For example, the forming of the lower barrier layer may include performing a physical vapor deposition (PVD) process.

Next, a lower insulating layer LIL may be formed on (e.g., at least partially to cover) the side surfaces of the lower conductive pattern LCP and the lower barrier pattern LBM. For example, an inner side surface of the lower insulating layer LIL may be roughened. For example, a process of forming the lower insulating layer LIL may be similar to the process of forming the upper insulating layer UIL described with reference to FIG. 9. In the process of forming the lower insulating layer LIL, the lower conductive pattern LCP and the lower barrier pattern LBM may be formed to have smooth upper surfaces, but embodiments of the inventive concepts are not limited thereto.

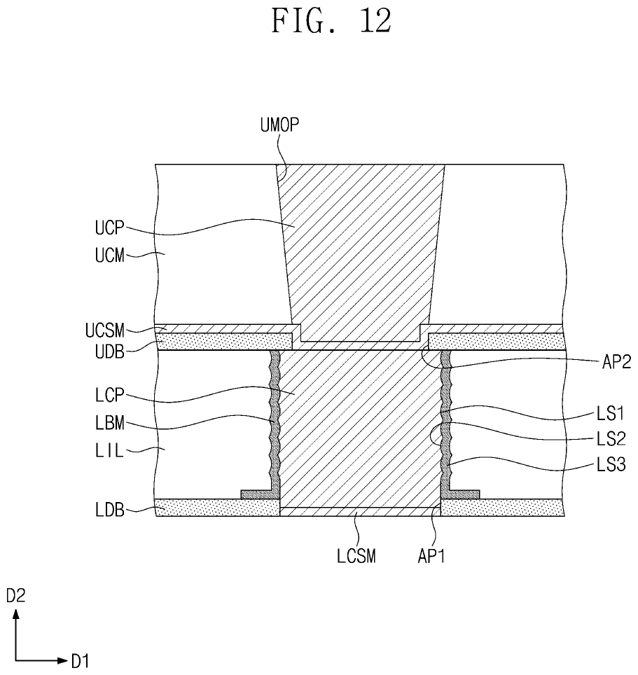

Referring to FIG. 12, an upper diffusion barrier layer UDB may be formed on the lower conductive pattern LCP. For example, a process of forming the upper diffusion barrier layer UDB may be similar to the process of forming the lower diffusion barrier layer LDB described with reference to FIG. 10. For example, the upper diffusion barrier layer UDB may be formed to have a second aperture AP2, and the second aperture AP2 may be formed on the lower conductive pattern LCP. For example, the second aperture AP2 may expose the lower conductive pattern LCP thereunder to the outside.

Thereafter, an upper conductive seed UCSM may be formed on (e.g., at least partially to cover) an upper surface of the upper diffusion barrier layer UDB and an inner surface of the second aperture AP2. For example, the formation of the upper conductive seed UCSM may be substantially the same or similar as described with reference to FIG. 7.

An upper conductive pattern UCP may be formed on the upper conductive seed UCSM. The formation of the upper conductive pattern UCP may be substantially the same or similar as described with reference to FIG. 7.

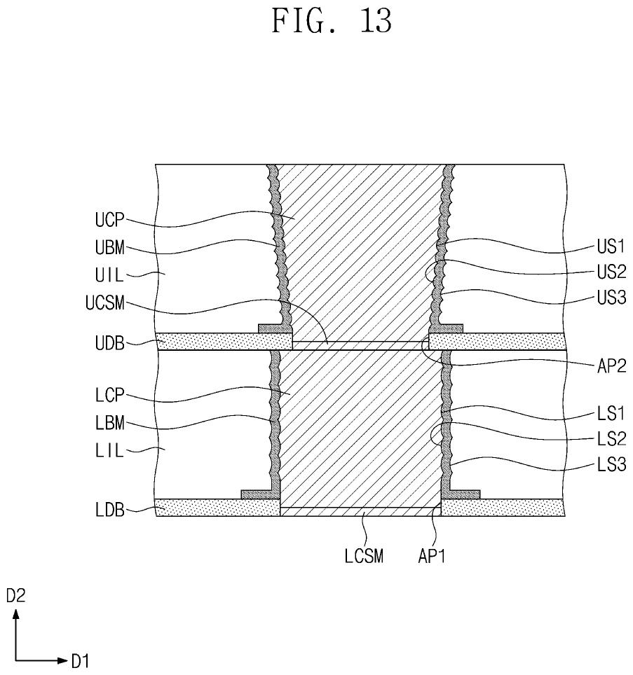

Referring to FIG. 13, a side surface US1 of the upper conductive pattern UCP may be roughened. The roughening process may be substantially the same or similar as described with reference to FIG. 8.

Thereafter, an upper barrier pattern UBM may be formed on (e.g., at least partially to cover) the side surface US1 of the upper conductive pattern UCP and the upper surface of the upper diffusion barrier layer UDB. An inner side surface US2, an outer side surface US3, and an upper surface of the upper barrier pattern UBM may be roughened. For example, a process of forming the upper barrier pattern UBM may be similar to the process of forming the lower barrier pattern LBM described with reference to FIG. 11.

An upper insulating layer UIL may be formed on (e.g., at least partially to cover) the side surfaces of the upper conductive pattern UCP and the upper barrier pattern UBM. For example, an inner side surface of the upper insulating layer UIL may be roughened. The formation of the upper insulating layer UIL may be substantially the same or similar as described with reference to FIG. 9. In the process of forming the upper insulating layer UIL, the upper conductive pattern UCP and the upper barrier pattern UBM may be formed to have smooth upper surfaces, but embodiments of the inventive concepts are not limited thereto.

According to the inventive concepts, the lower insulating layer LIL may be formed after the formation of the lower conductive pattern LCP. The upper insulating layer UIL may be formed after the formation of the upper conductive pattern UCP. Thus, a removal process (e.g., an etching process) of each of the lower insulating layer LIL and the upper insulating layer UIL may be omitted. As a result, each of the lower insulating layer LIL and the upper insulating layer UIL may not be damaged by the removal process. Thus, reliability of the semiconductor device may be improved.

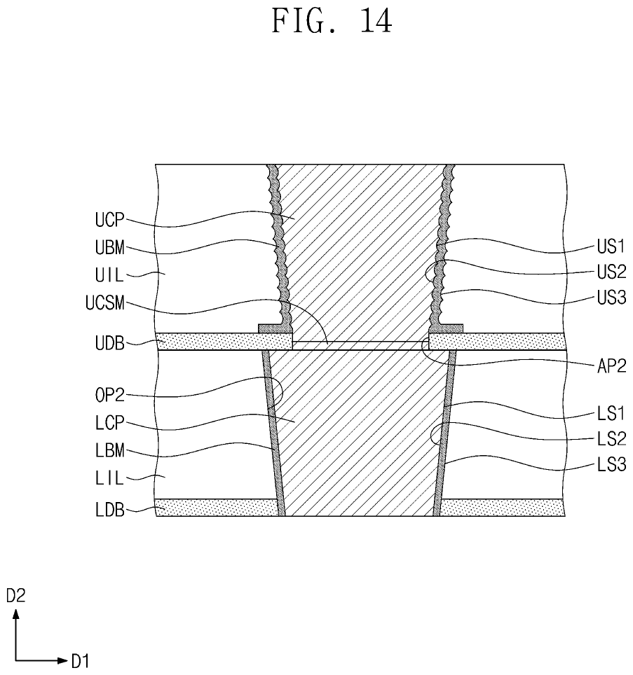

FIG. 14 is a cross-sectional view illustrating a method of manufacturing a semiconductor device according to some embodiments of the inventive concepts.

FIG. 14 may illustrate a method of manufacturing the conductive structure CS described with reference to FIGS. 2 and 6.

Referring to FIG. 14, a lower diffusion barrier layer LDB and a lower insulating layer LIL may be formed. In the case in which the plurality of conductive structures CS' and CS is formed as shown in FIG. 6, the lower diffusion barrier layer LDB and the lower insulating layer LIL may be sequentially formed on the upper conductive pattern UCP of one of the plurality of conductive structures CS' and CS thereunder.

A second opening OP2 may be formed in (e.g., to extend in or to penetrate) the lower diffusion barrier layer LDB and the lower insulating layer LIL. A process of forming the second opening OP2 may be similar to the process of forming the first opening OP1 described with reference to FIG. 7. The second opening OP2 may be formed on the upper conductive pattern UCP of one of the plurality of conductive structures CS' and CS thereunder. For example, the second opening OP2 may expose the upper conductive pattern UCP of one of the conductive structures CS' and CS thereunder to the outside.

A lower barrier pattern LBM and a lower conductive pattern LCP may be sequentially formed in the second opening OP2. A process of forming the lower barrier pattern LBM may be similar to the process of forming the first lower barrier pattern LBM1 described with reference to FIG. 7. The formation of the lower conductive pattern LCP may include forming a lower conductive seed (not shown) on (e.g., at least partially covering or overlapping) an inner surface of the second opening OP2 (and/or an inner surface of the lower barrier pattern LBM), forming a lower conductive layer (not shown) which fills (a remaining portion of) the second opening OP2 and covers an upper surface of the lower insulating layer LIL, and removing an upper portion of the lower conductive layer. A remaining portion of the lower conductive layer, which is not removed in the removal process, may be formed into the lower conductive pattern LCP. For example, the removal of the upper portion of the lower conductive layer may include performing a chemical mechanical polishing (CMP) process on the lower conductive layer. In some embodiments, a roughening process on the side surface LS1 of the lower conductive pattern LCP may be omitted. For example, the side surface LS1 of the lower conductive pattern LCP may be smooth, but embodiments of the inventive concepts are not limited thereto.

Thereafter, an upper diffusion barrier layer UDB, an upper conductive seed UCSM, an upper conductive pattern UCP, an upper barrier pattern UBM, and an upper insulating layer UIL may be formed on the lower conductive pattern LCP. The formation of the upper diffusion barrier layer UDB, the upper conductive seed UCSM, the upper conductive pattern UCP, the upper barrier pattern UBM, and the upper insulating layer UIL may be substantially the same or similar as described with reference to FIGS. 12 and 13.

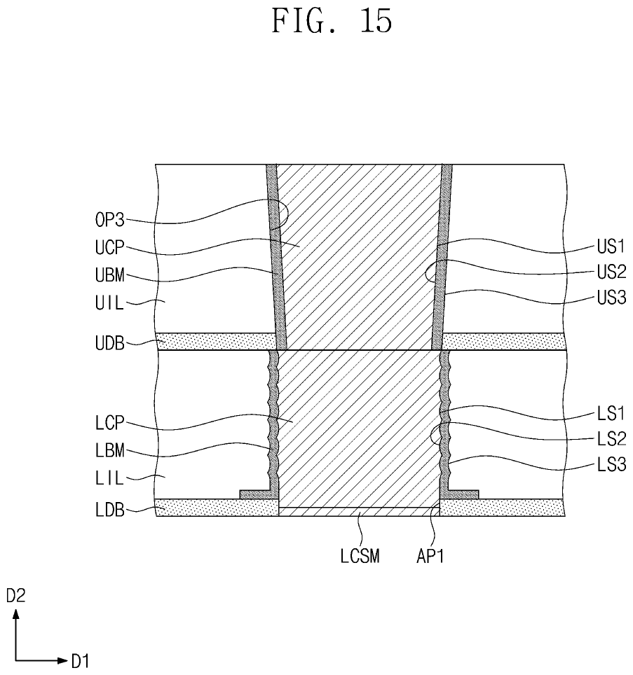

FIG. 15 is a cross-sectional view illustrating a method of manufacturing a semiconductor device according to some embodiments of the inventive concepts.

FIG. 15 may illustrate a method of manufacturing the conductive structure CS described with reference to FIGS. 3 and 6.

Referring to FIG. 15, a lower diffusion barrier layer LDB, a lower conductive seed LCSM, a lower conductive pattern LCP, a lower barrier pattern LBM, and a lower insulating layer LIL may be formed. In the case in which the plurality of conductive structures CS' and CS is formed as shown in FIG. 6, the lower diffusion barrier layer LDB, the lower conductive seed LCSM, the lower conductive pattern LCP, the lower barrier pattern LBM, and the lower insulating layer LIL may be formed on the upper conductive pattern UCP one of the plurality of conductive structures CS' or CS thereunder. The formation of the lower diffusion barrier layer LDB, the lower conductive seed LCSM, the lower conductive pattern LCP, the lower barrier pattern LBM, and the lower insulating layer LIL may be substantially the same or similar as described with reference to FIGS. 10 and 11.

Thereafter, an upper diffusion barrier layer UDB and an upper insulating layer UIL may be sequentially formed on the lower conductive pattern LCP.

A third opening OP3 may be formed in (e.g., to extend in or to penetrate) the upper diffusion barrier layer UDB and the upper insulating layer UIL. A process of forming the third opening OP3 may be similar to the process of forming the first opening OP1 described with reference to FIG. 7. The third opening OP3 may be formed on the lower conductive pattern LCP of one of the plurality of conductive structures CS' and CS thereunder. For example, the third opening OP3 may expose the lower conductive pattern LCP to the outside.

An upper barrier pattern UBM and an upper conductive pattern UCP may be sequentially formed in the third opening OP3. A process of forming the upper barrier pattern UBM may be similar to the process of forming the first lower barrier pattern LBM1 described with reference to FIG. 7. A process of forming the upper conductive pattern UCP may be similar to the process of forming the lower conductive pattern LCP described with reference to FIG. 14.

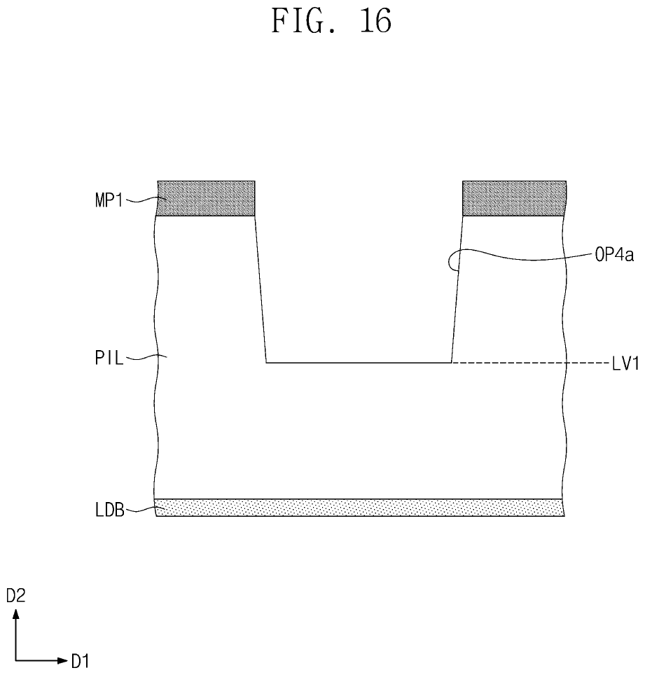

FIGS. 16 to 18 are cross-sectional views illustrating a method of manufacturing a semiconductor device according to some embodiments of the inventive concepts.

FIGS. 16 to 18 may illustrate a method of manufacturing the conductive structure CS described with reference to FIGS. 4 and 6.

Referring to FIG. 16, a lower diffusion barrier layer LDB and a preliminary insulating layer PIL may be formed. In the case in which the plurality of conductive structures CS' and CS is formed as shown in FIG. 6, the lower diffusion barrier layer LDB and the preliminary insulating layer PIL may be sequentially formed on the upper conductive pattern UCP of one of the plurality of conductive structures CS' and CS thereunder.

An upper portion OP4a of a fourth opening OP4 may be formed in (e.g., to extend in or to penetrate) the preliminary insulating layer PIL. The upper portion OP4a of the fourth opening OP4 may be formed at a level higher than a first level LV1. For example, the formation of the upper portion OP4a of the fourth opening OP4 may include forming a first mask pattern MP1 on the preliminary insulating layer PIL, and performing a removal process on the preliminary insulating layer PIL by using the first mask pattern MP1 as an etch mask. For example, in the removal process, the preliminary insulating layer PIL may be removed to the first level LV1.

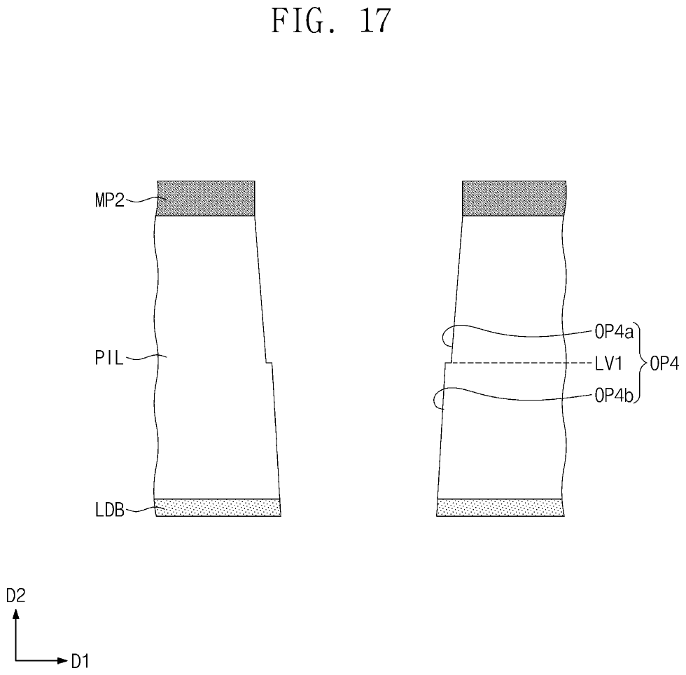

Referring to FIG. 17, a lower portion OP4b of the fourth opening OP4 may be formed in (e.g., to extend in or to penetrate) the lower diffusion barrier layer LDB and the preliminary insulating layer PIL. The lower portion OP4b of the fourth opening OP4 may be formed at a level lower than the first level LV1. For example, the formation of the lower portion OP4b of the fourth opening OP4 may include forming a second mask pattern MP2 on the preliminary insulating layer PIL, and performing a removal process on the preliminary insulating layer PIL by using the second mask pattern MP2 as an etch mask. An inner side surface of the preliminary insulating layer PIL, an inner side surface of the lower diffusion barrier layer LDB, and an upper surface of the upper conductive pattern UCP of one of the plurality of conductive structures CS' and CS thereunder may be exposed by the removal process. A width of the upper portion OP4a of the fourth opening OP4 (in the first direction D1) may be greater than a width of the lower portion OP4b of the fourth opening OP4 (in the first direction D1). The upper portion OP4a of the fourth opening OP4 may vertically overlap with the lower portion OP4b of the fourth opening OP4. The fourth opening OP4 may include the upper portion OP4a of the fourth opening OP4 and the lower portion OP4b of the fourth opening OP4. The fourth opening OP4 may have a stepped structure at the first level LV1.

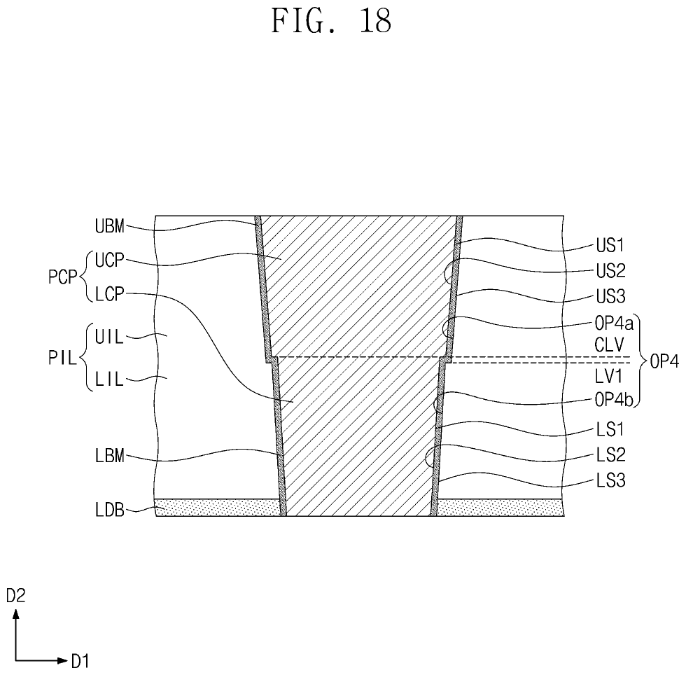

Referring to FIG. 18, a lower barrier pattern LBM and an upper barrier pattern UBM may be formed in the fourth opening OP4 by the same process or by the same series of processes.

Next, a preliminary conductive pattern PCP may be formed in the fourth opening OP4. For example, the formation of the preliminary conductive pattern PCP may include forming a preliminary conductive seed (not shown) on (e.g., at least partially covering or overlapping) an inner surface of the fourth opening OP4, forming a preliminary conductive layer (not shown) which fills (a remaining portion of) the fourth opening OP4 and covers an upper surface of the preliminary insulating layer PIL, and removing an upper portion of the preliminary conductive layer. A remaining portion of the preliminary conductive layer, which is not removed in the removal process, may be formed into the preliminary conductive pattern PCP. The preliminary conductive pattern PCP may include an upper conductive pattern UCP and a lower conductive pattern LCP. The upper conductive pattern UCP and the lower conductive pattern LCP may be distinguished from each other at the contact level CLV without an interface (e.g., a visible interface) therebetween and may be in contact with each other.

The preliminary insulating layer PIL may include a lower insulating layer LIL and an upper insulating layer UIL. For example, the lower insulating layer LIL and the upper insulating layer UIL may be distinguished from each other at the contact level CLV without an interface (e.g., a visible interface) therebetween and may be in contact with each other.

According to the inventive concepts, the side surfaces of the upper conductive pattern and the lower conductive pattern may be roughened. Thus, a contact area between the upper conductive pattern and the upper insulating layer and a contact area between the lower conductive pattern and the lower insulating layer may be widened. As a result, the adhesion therebetween may be increased or enhanced to prevent a delamination phenomenon and a crack. Thus, the reliability of the semiconductor device may be improved.

According to the inventive concepts, a removal process (e.g., an etching process) of each of the lower insulating layer and the upper insulating layer may be omitted. Thus, each of the lower insulating layer and the upper insulating layer may not be damaged by the removal process. As a result, the reliability of the semiconductor device may be improved.

While the embodiments of the inventive concepts have been particularly shown and described, it will be understood by one of ordinary skill in the art that variations in form and detail may be made therein without departing from the spirit and scope of the attached claims.

What is claimed is:

1. A semiconductor device comprising:
a substrate; and
a conductive structure on the substrate,
wherein the conductive structure comprises:
a lower conductive structure comprising a lower conductive pattern; and
an upper conductive structure comprising an upper conductive pattern,
wherein the upper conductive structure is on the lower conductive structure,
wherein at least one of a side surface of the lower conductive pattern or a side surface of the upper conductive pattern comprises a rough surface, and
wherein a first width of a lower surface of the upper conductive pattern in a first direction parallel to a lower surface of the substrate is substantially equal to or less than a second width of an upper surface of the lower conductive pattern in the first direction.

2. The semiconductor device of claim 1, wherein each of the lower conductive pattern and the upper conductive pattern includes at least one of Cu, Au, Al, or Ru.

3. The semiconductor device of claim 1, wherein the lower conductive pattern and the upper conductive pattern are in contact with each other with an interface interposed therebetween.

4. The semiconductor device of claim 1, wherein the lower conductive structure further comprises a lower barrier pattern on the side surface of the lower conductive pattern,
wherein the upper conductive structure further comprises an upper barrier pattern on the side surface of the upper conductive pattern, and
wherein at least one of an inner side surface of the lower barrier pattern or an inner side surface of the upper barrier pattern comprises a rough surface.

5. The semiconductor device of claim 4, wherein the side surface of the upper conductive pattern comprises a rough surface, and
wherein the inner side surface of the upper barrier pattern comprises a rough surface.

6. The semiconductor device of claim 4, wherein the side surface of the lower conductive pattern comprises a rough surface, and
wherein the inner side surface of the lower barrier pattern comprises a rough surface.

7. The semiconductor device of claim 4, wherein the upper conductive structure further comprises an upper diffusion barrier layer under the upper barrier pattern,
wherein the side surface of the upper conductive pattern comprises a rough surface, and
wherein the upper barrier pattern is spaced apart from the lower conductive pattern by the upper diffusion barrier layer.

8. The semiconductor device of claim 4, wherein the side surface of the upper conductive pattern comprises a rough surface, and
wherein a portion of the upper barrier pattern extends in the first direction on the upper surface of the lower conductive pattern.

9. The semiconductor device of claim 4, wherein the side surface of the upper conductive pattern comprises a rough surface, and
wherein a lower surface of the upper barrier pattern is farther than the lower surface of the upper conductive pattern from the lower surface of the substrate in a second direction that is perpendicular to the lower surface of the substrate.

10. The semiconductor device of claim 4, wherein the lower conductive structure further comprises a lower diffusion barrier layer under the lower barrier pattern,
wherein the side surface of the lower conductive pattern comprises a rough surface, and
wherein the lower barrier pattern is in contact with an upper surface of the lower diffusion barrier layer.

11. The semiconductor device of claim 4, wherein the lower conductive structure further comprises a lower diffusion barrier layer,
wherein the lower barrier pattern is on the lower diffusion barrier layer,
wherein the side surface of the lower conductive pattern comprises a rough surface, and
wherein a portion of the lower barrier pattern extends in the first direction on an upper surface of the lower diffusion barrier layer.

12. The semiconductor device of claim 4, wherein the side surface of the lower conductive pattern comprises a rough surface, and
wherein a lower surface of the lower barrier pattern is farther than a lower surface of the lower conductive pattern from the lower surface of the substrate in a second direction that is perpendicular to the lower surface of the substrate.

13. The semiconductor device of claim 1, wherein the lower conductive structure further comprises a lower insulating layer on the side surface of the lower conductive pattern,
wherein the upper conductive structure further comprises an upper insulating layer on the side surface of the upper conductive pattern, and
wherein at least one of an inner side surface of the lower insulating layer or an inner side surface of the upper insulating layer comprises a rough surface.

14. A semiconductor device comprising:
a substrate; and
a conductive structure on the substrate,
wherein the conductive structure comprises:
a lower conductive structure comprising a lower conductive pattern; and
an upper conductive structure comprising an upper conductive pattern,
wherein the upper conductive structure is on the lower conductive structure,
wherein at least one of a side surface of the lower conductive pattern or a side surface of the upper conductive pattern comprises a rough surface, and
wherein the upper conductive pattern and the lower conductive pattern are in contact with each other with an interface interposed therebetween.

15. The semiconductor device of claim 14, wherein the lower conductive structure further comprises a lower barrier pattern on the side surface of the lower conductive pattern,
wherein the upper conductive structure further comprises an upper barrier pattern on the second side surface of the upper conductive pattern, and
wherein at least one of an inner side surface of the lower barrier pattern or an inner side surface of the upper barrier pattern comprises a rough surface.

16. The semiconductor device of claim 14, wherein the lower conductive structure further comprises a lower insulating layer on the side surface of the lower conductive pattern,
wherein the upper conductive structure further comprises an upper insulating layer on the side surface of the upper conductive pattern, and
wherein at least one of an inner side surface of the lower insulating layer or an inner side surface of the upper insulating layer comprises a rough surface.

17. A semiconductor device comprising:
a substrate; and
a first conductive structure on the substrate and a second conductive structure on the first conductive structure,
wherein each of the first and second conductive structures comprises:
a lower conductive structure comprising a lower conductive pattern; and
an upper conductive structure comprising an upper conductive pattern,
wherein at least one of a side surface of the lower conductive pattern of the second conductive structure or a side surface of the upper conductive pattern of the second conductive structure comprises a rough surface, and
wherein a width of a lower surface of the upper conductive pattern in a first direction parallel to a lower surface of the substrate is substantially equal to or less than a width of an upper surface of the lower conductive pattern in the first direction.

18. The semiconductor device of claim 17, wherein at least one of a side surface of the lower conductive pattern of the first conductive structure or a side surface of the upper conductive pattern of the first conductive structure comprises a rough surface.

19. The semiconductor device of claim 17, wherein side surfaces of the lower and upper conductive patterns of the first conductive structure comprise smooth surfaces.

20. The semiconductor device of claim 17, further comprising:
at least one additional conductive structure between the first conductive structure and the second conductive structure.
